(19) United States
(12) Patent Application Publication
(10) Pub. No.: US 2004/0086012 A1
(43) Pub. Date: May 6, 2004

(54) Coherent light source and method for driving the same

(75) Inventors: Yasuo Kitaoka, Ibaraki-shi (JP); Kazuhisa Yamamoto, Takatsuki-shi (JP)

Correspondence Address: MERCHANT & GOULD PC, P.O. BOX 2903, MINNEAPOLIS, MN, 55402-0903, US

(73) Assignee: Matsushita Electric Industrial Co., Ltd, Kadoma-shi (JP)

(21) Appl. No.: 10/692,158

(22) Filed: Oct. 22, 2003

(30) Foreign Application Priority Data
Oct. 23, 2002 (JP) 2002-308227

(51) Int. Cl. H01S 3/13; H01S 5/00

(52) U.S. Cl. 372/43; 372/32

(57) ABSTRACT

A coherent light source includes a two-electrode laser diode provided with an active region having an active layer that emits light due to injection of a current, and a phase control region that has a layer that is disposed contiguous with the active layer and in which a change in refractive index is caused by injection of current, and an optical waveguide device in which a DBR (distributed Bragg reflector) region is formed. Laser light that is emitted from the two-electrode laser diode is optically coupled into an optical waveguide of the optical waveguide device, and a portion of the laser light that is emitted from the two-electrode laser diode is reflected by the DBR region and returned to the two-electrode laser diode, thereby locking an oscillation wavelength. Since it is not necessary to form a DBR region on the laser diode, stable wavelength control and modulation control can be achieved at low-cost.

### FIELD OF THE INVENTION

The present invention is related to coherent light sources that are composed with a laser diode and that are used in the field of optical communications and optical information processing.

### BACKGROUND OF THE INVENTION

In recent years, variable-wavelength laser diodes have been considered for application in the field of optical communications and as sources for generating a fundamental wave for generating second harmonics by employing non-linear effects. Distributed feedback (DFB) laser diodes and distributed Bragg reflector (DBR) laser diodes, in which a grating is integrated onto a laser diode, are laser diodes in which the laser itself is capable of single longitudinal mode oscillation. Tuning the oscillation wavelength by injecting current into the DBR portion on a DBR laser diode to effect a change in the refractive index through plasma effects or a temperature change has been proposed as a method for varying the wavelength.

A DBR laser diode having a wavelength varying function is described with reference to FIG. 8. FIG. 8 shows an overview of the configuration of an AlGaAs variable-wavelength DBR laser diode having a three-electrode structure. An AlGaAs double heterostructure including an active layer 33 is formed on an n-GaAs substrate 30. An n-side electrode 42a and a p-side electrode 42b for injecting current are formed on the n-side and the p-side, respectively, of the n-GaAs substrate 30. This element is divided in the resonator direction into an active region 43, a phase control region 44, and a DBR region 45, and in the DBR region 45 and the phase control region 44, the active layer 33 has been disordered by doping silicon. Also, a grating 36 is formed in the DBR region 45.

In such AlGaAs variable-wavelength DBR laser diodes having a three-electrode structure, for example, with the threshold value at 25 mA, an output of 90 mW is obtained in response to the injection of a 150 mA current (operation current Ip) to the active region 33. Also, by changing the current injected to the DBR region (DBR current Idbr) to thermally change the refractive index of the DBR region 45, a wavelength variability of about 2 nm is attained. The oscillation wavelength is kept in a single longitudinal mode even while the wavelength is variable. Also, when the relationship between the DBR current Idbr and the current injected to the phase control region 44 (phase current Iph) is held at Idbr/Iph=0.63 and control is performed simultaneously, it is possible to achieve continuous wavelength variability (for example, see page 4 and FIG. 3 and FIG. 5 of JP S63-147387A).

The process for manufacturing this DBR laser diode is described with reference to FIG. 9. In a first epitaxial growth using a MOCVD (metal organic chemical vapor deposition) device, an n-GaAs buffer layer 31, a first cladding layer 32, an active layer 44, a second cladding layer 34, a first light guide layer 35, and a layer (not shown in the drawing) for forming a grating 36 are formed in that order on an n-GaAs substrate 30. Then, a resist (not shown in the drawing) is applied onto the layer for forming the grating 36, a periodic structure is formed by interference exposure or EB (electron beam) exposure, and then the periodic structure is transferred through etching to form the grating 36. Next, through ion injection or heat diffusion, the active layer 33 of the DBR region 45 and the phase control region 44 are disordered, forming a passive optical waveguide.

Next, in a second growth, a second light guide layer 37, a third cladding layer 38, and a current block layer 39 made of p-AlGaAs are formed in that order. A photolithography technique is then used to form a striped window 39a in the current block layer 39, forming a rib waveguide. Then, in a third growth, a fourth cladding layer 40 and a contact layer are formed in that order. The contact layer is then separated into an active region contact layer 41a, a phase control region contact layer 41b, and a DBR region contact layer 41c. Although not shown, lastly, electrodes for injection of current are formed on the n-side and the p-side.

In variable-wavelength DBR laser diodes and DFB laser diodes, single mode characteristics and wavelength variability are very important. To meet the requirements for these characteristics, the uniformity of the DBR region formed on the laser diode is crucial. This is because the uniformity of the DBR region affects the reflection characteristics. Of the reflection characteristics, the reflectance significantly affects the oscillation characteristics of the laser diode and changes the threshold value and the slope efficiency. Also, the characteristics of the reflection spectrum significantly affect the single mode characteristics, and double-peak characteristics or broad reflection characteristics cause multi-longitudinal mode oscillation.

A problem with forming a DBR region on a laser diode is that it is difficult to form a uniform grating in large wafers, such as two or three inch wafers. Also, as discussed above, normally when forming a grating, the periodic structure of a resist is formed on a layer formed in the first growth and then the periodic structure is transferred by etching. After formation of the grating, various additional processing is performed.

Consequently, regarding the grating,

1) discrepancies in the periodic structure of the resist,

2) discrepancies in the ability to control transfer through etching, and

3) discrepancies in the ability to control, for example, further growth significantly affect the reflectance of the DBR region and the characteristics of the spectrum width. As a result, the threshold value, the slope efficiency, the single mode characteristics, and the wavelength variability, for example, of a variable-wavelength DBR laser diode may be made worse.

An additional problem is that with AlGaAs laser diodes, the plasma effect is small and the speed at which wavelengths can be changed is slow. Also, although methods for using an external grating in an ordinary Fabry-Perot semiconductor have been proposed, with a configuration that adopts a reflecting grating or a fiber grating, for example, it is difficult to fine tune the continuous wavelength variability, that is, the phase state within the resonator.

### SUMMARY OF THE INVENTION

The present invention solves the above problems, and it is an object thereof to provide a coherent light source with which stable wavelength variability and modulation characteristics can be achieved, that has a simple configuration, and that can be produced easily.

A coherent light source of the present invention includes a two-electrode laser diode provided with an active region having an active layer that emits light due to injection of a current, and a phase control region that has a layer that is disposed contiguous with the active layer and in which a change in refractive index is caused by injection of current, and an optical waveguide device in which a DBR (distributed Bragg reflector) region is formed. The laser light that is emitted from the two-electrode laser diode is optically coupled into an optical waveguide of the optical waveguide device, and a portion of the laser light that is emitted from the two-electrode laser diode is reflected by the DBR region and returned to the two-electrode laser diode, thereby locking an oscillation wavelength.

### BRIEF DESCRIPTION OF THE DRAWINGS

FIG. 1 is a cross-sectional view showing the coherent light source according to a first embodiment of the present invention.

FIG. 2A and FIG. 2B are cross-sectional views showing the two-electrode laser configured having this coherent light source.

FIG. 3 is a perspective view that shows in detail the structure of this two-electrode laser diode.

FIG. 4 is a cross-sectional view showing the SHG device applied for composing the coherent light source of FIG. 1.

FIG. 5A and FIG. 5B are views showing the wavelength variability of the two-electrode laser diode according to the first embodiment.

FIG. 6A and FIG. 6B are waveform views showing the method for driving the coherent light source according to a second embodiment.

FIG. 7 is a cross-sectional view showing the coherent light source according to a third embodiment of the present invention.

FIG. 8 is a cross-sectional view showing a conventional example of a DBR laser diode having a three-electrode structure.

FIG. 9 is a perspective view showing in detail the conventional example of the DBR laser diode having a three-electrode structure.

### DESCRIPTION OF THE PREFERRED EMBODIMENTS

A coherent light source of the present invention is made by combining a two-electrode laser diode provided with an active region and a phase control region, and an optical waveguide device in which a DBR (distributed Bragg reflector) region is formed. Consequently, a DBR region that has stable characteristics not restricted by the structure of the laser diode or affected by the manufacturing process can be obtained. As a result, stable wavelength control and modulation control of the laser diode is possible. Also, since it is not necessary to form the DBR region on the laser diode, a low-cost, stable coherent light source can be provided.

In the coherent light source of the present invention it is preferable that an emission end face of the two-electrode laser diode and an incidence end face of the optical waveguide device are in opposition to one another, and that the laser light emitted from the two-electrode laser diode is optically coupled directly into the optical waveguide of the optical waveguide device. The laser light that is emitted from the two-electrode laser diode may be optically coupled into the optical waveguide of the optical waveguide device via an optical fiber.

The phase control region may be formed so as to have an active layer that is contiguous with the active layer of the active region and that has been disordered, so that an injection of current causes a change in refractive index but does not cause laser oscillation. Thus, a passive optical waveguide can be formed easily. The optical waveguide device may be a wavelength conversion device that employs second harmonic generation. An electrode may be formed in the phase control region, and by applying current or voltage via the electrode, a phase state inside a resonator of the two-electrode laser diode is changed.

It is preferable that the DBR region is disposed substantially adjacent to the emission end face of the laser diode-side. Thus, the emission end face of the laser diode and the reflecting surface of the DBR region operate substantially equally, allowing a stable resonator to be achieved.

It is also preferable that an inactive region where the active layer has been disordered is formed in an end face portion of the two-electrode laser diode, and that current is not injected into the inactive region. It is further preferable that a wavelength difference between a phase matching wavelength of the wavelength conversion device and a DBR wavelength of the DBR region is not more than 2 nm. It is further preferable that in an operation temperature range, a phase matching wavelength of the wavelength conversion device is longer than a DBR wavelength of the DBR region. The optical waveguide device may be an optical modulator.

In a method for driving the coherent light source configured as above, it is possible for a current and a voltage that are supplied to the DBR region and the phase control region to be changed simultaneously to allow an oscillation wavelength of the laser diode to be changed continuously rather than discretely.

Also, in a method for driving the coherent light source configured as above, it is preferable that modulation of an output intensity of the laser diode is performed by changing a current and a voltage that are supplied to the active region and the phase control region at reversed phases. Thus, fluctuation, for example, in the wavelength that accompanies modulation is inhibited, allowing a stable single mode oscillation to be attained.

Embodiments of the present invention are described in detail below with reference to the drawings.

First Embodiment

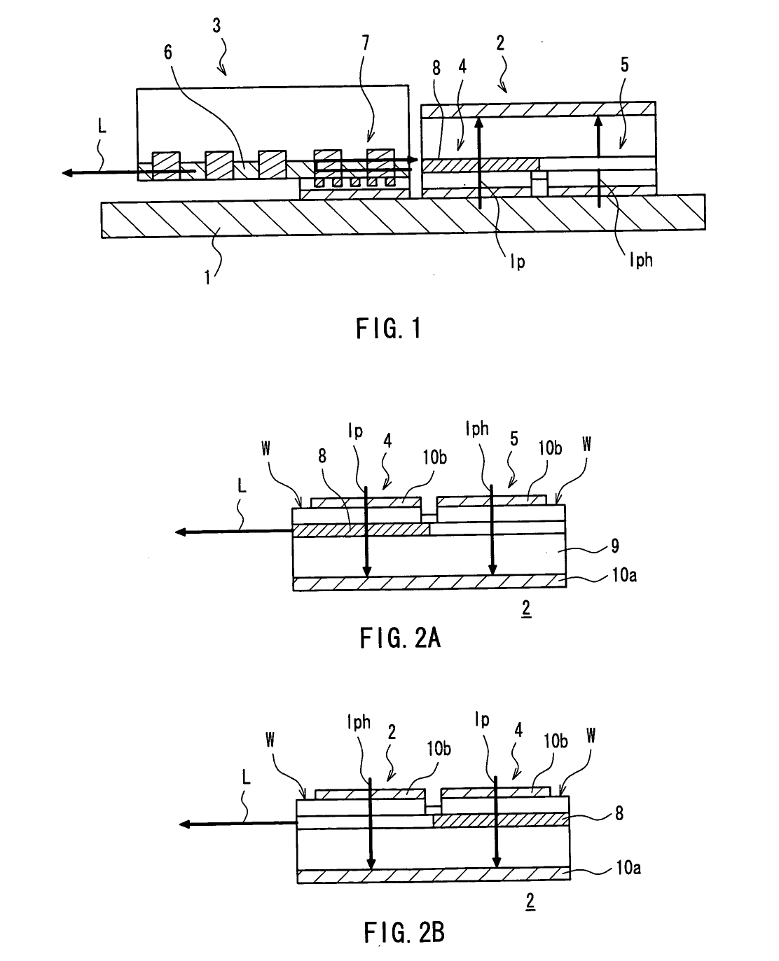

FIG. 1 shows an overview of the configuration of a coherent light source according to a first embodiment of the present invention. This coherent light source is a short-wavelength light source made of a two-electrode laser diode 2 mounted onto a Si sub-mount 1 and an optical waveguide-type SHG (second harmonic generation) device 3. The two-electrode laser diode 2 has an active region 4 and a phase control region 5. The SHG device 3 has an optical waveguide 6 and is provided with a DBR region 7 on its side facing the two-electrode laser diode 2.

The two-electrode laser diode 2 is fixed face-down on the Si sub-mount 1. The SHG device 3 is fixed by a UV-light cured agent with its optical waveguide 6 facing the Si sub-mount 1. The emission end face of the two-electrode laser diode 2 and the incidence end face of the SHG device 3 are opposed to one another in such a manner that the optical axes of an active layer 8 of the two-electrode laser diode 2 and the optical waveguide 6 of the SHG device 3 are matching. The distance between these two end faces is set to about 1 μm, which means two end faces substantially are in contact with one another. An incidence end face of the DBR region 7 is positioned at the incidence end face of the SHG device 3. Therefore the DBR region 7 is disposed substantially adjacent to the emission end face of the two-electrode laser diode 2.

The two-electrode laser diode 2 constituting the above coherent light source is described in detail below with reference to FIG. 2A. The two-electrode laser diode 2 has an AlGaAs double heterostructure that includes the active layer 8 and that is formed on an n-GaAs substrate 9, and this structure is divided in the resonator direction into an active region 4 and a phase control region 5. An n-side electrode 10a is formed on the lower surface of the substrate 1, and a p-side electrode 10b split between the active region 4 and the phase control region 5 is formed above the double heterostructure. The active layer 8 of the phase control region 5 has been disordered. Consequently, by injecting the currents Ip and Iph from the electrodes 10a and 10b, the active layer 8 of the active region 4 emits light, but the active layer 8 of the phase control region 5 does not emit light and only its refractive index is changed. FIG. 2A shows a structure in which laser light is obtained from the end face on the active region 4 side, but as shown in FIG. 2B, it is also possible to adopt a structure in which laser light is obtained from the end face on the phase control region 5 side.

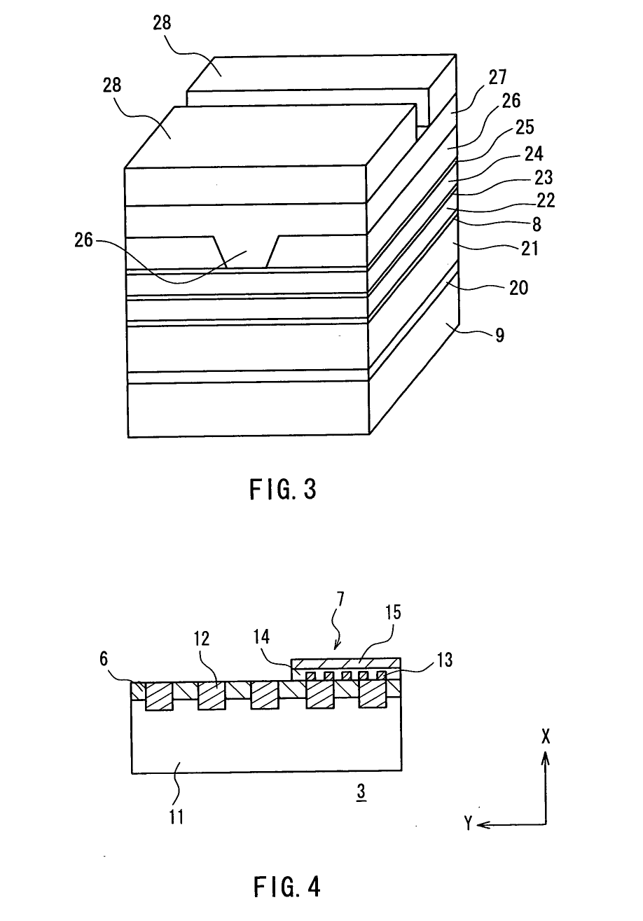

In the process for manufacturing the two-electrode laser diode 2, an AlGaAs double heterostructure is formed on the GaAs substrate 9 in a first growth using MOCVD. A current blocking layer is formed on this structure, and then a waveguide stripe (depicted in FIG. 3) is formed through etching. Next, through ion implantation or the thermal diffusion of impurities, the phase control region 5 and the active layer 8 of a window structure portion W of the end face are disordered. Then, a second crystal growth is carried out, forming a cladding layer and a contact layer, and lastly, the electrodes 10a and 10b are formed. In the window structure portion W of the end face, the electrodes are removed to electrically separate the active region 4 and the phase control region 5, creating a portion into which current is not injected.

The wafer that is obtained is cleaved and its end faces are coated, and then it is secondarily cleaved and made into chips. In this embodiment, the reflectance of the end faces is for example 5% for the front end face and 95% for the rear end face. The manufacturing method described above is the same for infrared (AlGaAs) or red (AlGaInP) laser diodes having only an ordinary window structure, and it is suited for mass-production.

The manufacturing method for the two-electrode laser diode 2 according to this embodiment will be described with reference to FIG. 3 in order to compare it with the manufacturing method for the conventional DBR laser diode illustrated in FIG. 9.

First, in a first growth, an n-GaAs buffer layer 20, a first cladding layer 21, an active layer 8, a second cladding layer 22, a first light guide layer 23, a second light guide layer 24, a third cladding layer 25, and a current block layer 26 are formed in that order on the n-GaAs substrate 9. After a striped window 26a is formed in the current block layer 26, in a second growth a fourth cladding layer 27 and a contact layer are formed in that order. Then, the contact layer is separated into an active region contact layer 28a and a phase control region contact layer 28b.

As shown above, when the method for manufacturing the DBR laser diode and the method for manufacturing the two-element laser diode are compared, it is clear that with the DBR laser diode three epitaxial growth steps are required, whereas with the two-element laser diode it is not necessary to form the grating internally and thus only two epitaxial growth steps are required. In this way, the process can be simplified, making it suited for low-cost high-yield processing.

With respect to the resonator length, in the three-electrode DBR laser diode, for example, the active region is 700 μm, the phase control region is 300 μm, and the DBR region is 500 μm, yielding a chip length of about 1.5 mm. On the other hand, with the two-electrode laser diode according to this embodiment, there is no DBR region, and thus if the active region and the phase control region have the same configuration as above, then the chip length can be reduced to 1 mm. Consequently, the number of chips that can be obtained from a single wafer is increased, and this is suited for reducing costs.

Furthermore, since there is no DBR region, the characteristics that are required are not dependent on the DBR region, and the current-output characteristics, the far-field characteristics, and the reliability, for example, are obtained at substantially the same yield as for ordinary FP lasers.

Next, the optical waveguide SHG device 3 is described with reference to FIG. 4. The reference numeral 11 denotes a substrate, for which a 1.5 degree off-cut MgO:LiNbO₃ substrate doped with Mg to 5 mol % can be used. Periodic domain inverted regions 12 and an optical waveguide 6 perpendicular to the periodic domain inverted regions 12 are formed in the upper surface of the substrate 11. The periodic domain inverted regions 12 are formed in the entire region over which the optical waveguide 6 has been formed. A DBR grating 13 formed by a resist pattern is provided in the DBR region 7 at an end portion of the optical waveguide 6. A Ta₂O₅ film 14 that has a large refractive index and that covers the DBR grating 13 is formed on the optical waveguide 6, and a thin film heater 15 is formed on the film 14.

The periodic domain inverted regions 12 can be formed using any established method. For example, they can be formed using a method in which a comb-shaped electrode and a parallel electrode are formed on the +x surface of the substrate 11, and the comb-shaped electrode (period: 2.8 μm) is made the GND and a negative electric field (5 kV, 25 msec) is applied to the parallel electrode. The optical waveguide 6 may be formed through proton exchange, ion diffusion, or ridge processing. In a working example of this embodiment, proton exchange was used. That is, through proton exchange in pyrophosphoric acid, Li and H were exchanged to raise the refractive index, forming the optical waveguide 6. When the quasi-phase matching conditions based on the periodic domain inverted region 12 are satisfied and the wavelength of the fundamental wave matches the phase matching wavelength, highly efficient wavelength conversion is achieved.

The relationship between the period of the DBR grating 13 and the Bragg wavelength is expressed in the following formula:

2nΛ=mλ

Here, n is the effective refractive index (2.16), A is the polarization inversion period, m is an integer, and λ is the wavelength. Consequently, for example, to form a two-order (n=2) DBR grating 13 for a 820 nm wavelength, the mask can be designed so that its period is 380 nm. To form the DBR grating 13, a resist is applied onto the substrate 11 on which the periodic domain inverted regions 12 and the optical waveguide 6 are formed and the substrate is exposed to light via a mask to form the grating through the resist pattern. Then, the Ta₂O₅ film 14 is fabricated on the optical waveguide 6 through sputtering so that it covers the DBR grating 13.

The end faces of the SHG device 3 are provided preferably with antireflection coatings that do not reflect light at the wavelength emitted by the two-electrode laser diode 2. The reason for this is that since the refractive index of the LiNbO₃ substrate is 2.16, its reflectance is about 14%. Consequently, unless reflection is reduced, the reflection overlaps with the reflection from the DBR grating 13, lowering the ability to select that wavelength.

The reflection characteristics of the DBR grating 13 were measured, and it was found that a reflectance of about 20% was obtained for a DBR length of 0.5 mm. The full width at half maximum of the reflection spectrum at this time was narrow at about 0.6 nm. The longitudinal mode interval of the laser diode is also about 0.1 nm, but since the laser diode oscillates with a small loss difference, the above reflectance and spectrum width are sufficient for obtaining single longitudinal mode characteristics.

Next, the operation of the coherent light source according to this embodiment and shown in FIG. 1 is described. Advantages of this embodiment are achieved by the structure in which the emission end face of the two-electrode laser diode 2 substantially is in contact with the incidence end face of the SHG device 3, and the end of the DBR region 7 is positioned at the incidence end face of the SHG device 3.

The light emitted from the two-electrode laser diode 2 is optically coupled into the optical waveguide 6 of the optical waveguide SHG device 3. Some (in this embodiment, 20%) of the light propagating through the optical waveguide 6 is reflected by the DBR grating 13 and returns to the two-electrode laser diode 2. In such condition, a first resonator is formed between a rear end face on the phase control region 5 side of the two-electrode laser diode 2 and the emission end face of the two-electrode laser diode 2. Further, a second resonator is formed between the rear end face of the two-electrode laser diode 2 and the incidence end face of the DBR grating 13. In this embodiment, there is a very small difference between lengths of the first resonator and the second resonator, because the end of the DBR grating 13 is disposed very closely to the emission end face of the two-electrode laser diode 2, so that the emission end face of the two-electrode laser diode 2 and the reflective face of the DBR region 7 can be regarded as substantially identical. As a result, a stable resonator is formed. The remaining light that is not reflected by the DBR region 7 is obtained as the output light from the emission end face of the optical waveguide 6.

In order to obtain such effect, it is not necessary that the end face of the DBR region 7 is positioned just at the end face of the SHG device 3. The two end faces may be separated while being set substantially adjacent to one another within a range in which the incidence end face of the DBR region 7 forms substantially the same resonator as that formed by the emission end face of the two-electrode laser diode 2 based on the above mentioned effect. A tolerance may be similar in adjusting the contact condition between the emission end face of the two-electrode laser diode 2 and the incidence end face of the SHG device 3.

The two-electrode laser diode 2 is locked to the wavelength of the light that returns from the DBR region 7, and oscillates in a single longitudinal mode. With this coherent light source, since the end face of the two-electrode laser diode 2 and the end face of the DBR region 7 are near one another, the longitudinal mode of the two-electrode laser diode 2 is determined by the rear end face of the two-electrode laser diode 2 and the incidence end face of the optical waveguide 6 (the end face of the DBR region 7). Consequently, the longitudinal mode interval widens to a value that corresponds to a resonator length of 1 mm, that is, to about 0.1 μm, and thus a stable single longitudinal mode oscillation is achieved.

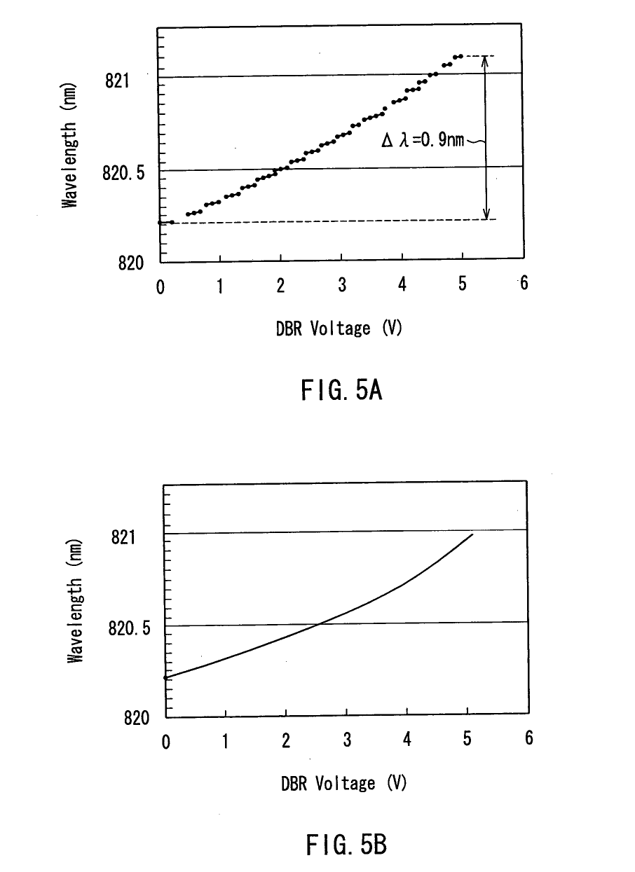

Also, the phase control region 5 of the two-electrode laser diode 2 does not contribute to oscillation, and only a change in the refractive index is caused, when current is injected. Thus, it can adjust the change in phase. For example, by allowing the current that is applied to the thin film heater 15 of the optical waveguide 6 of the SHG device 3 shown in FIG. 1 to be changed, it is possible to change the refractive index of the DBR region 7 and vary the phase of the light that returns from the DBR region 7, and therefore the wavelength of the two-electrode laser diode 2 can be changed continuously. As shown in FIG. 5A, in normal circumstances, the wavelength of a laser diode exhibits discrete wavelength variability for each interval of the longitudinal mode. On the other hand, with this embodiment, the two-electrode laser diode 2 has the phase control region 5, and thus as shown in FIG. 5B, continuous wavelength variability can be achieved.

As illustrated above, a first characteristic of the coherent light source of this embodiment is the combination of a two-electrode laser diode having a phase control region and an optical waveguide device having a DBR region. A preferable second characteristic thereof is that these two are directly optically coupled and that the end face of the DBR region is disposed closely to the end face of the optical waveguide device. The combination of the first characteristic and the second characteristic permits continuous wavelength variability and allows stable wavelength characteristics to be obtained even during the modulation operation. That is, since the DBR region 7 is separated from but sufficiently close to the two-electrode laser diode 2, stable single longitudinal mode oscillation is obtained and the wavelength can be changed continuously due to the action of the phase control region 5. In addition, the DBR region 7 is sufficiently thermally separated from the two-electrode laser diode 2 since they are separate bodies, so that heat generated in conjunction with the operation for directly modulating the laser diode does not substantially affect the operation of the DBR region 7, and as a result, the wavelength can be stabilized even during the modulation operation.

It should be noted that if, as shown in FIG. 2B, the two-electrode laser diode has a configuration in which laser light is obtained from its end face on the phase control region 5 side, then the phase control region 5 is interposed between the active region 4 and the DBR region 7. Since the active region 4 has larger thermal expansion than the phase control region 5, this configuration is even more advantageous than the configuration of FIG. 2A in terms of the effect of thermally isolating the DBR region 7 from the two-electrode laser diode 2.

In this embodiment, the current injected into the DBR region 7 on the SHG device 3 and the phase control region on the two-electrode laser diode 2 can be changed to allow the wavelength of the laser diode to be changed in a continuous manner. Thus, the wavelength of the laser diode can be matched easily to the phase matching wavelength of the SHG device 3 to allow highly efficient wavelength conversion to be achieved, and high-power violet light is obtained.

The change in the refractive index with respect to the temperature of the LiNbO₃ crystal is 4.5×10⁻⁵, and the wavelength fluctuation with respect to the temperature is 0.017 nm/° C. The obtained width of wavelength variation is about 0.9 nm, and the temperature change of the DBR region 7 corresponding to this is about 50° C. By further injecting current to the DBR region 7, the width of wavelength variation can be set to about 2 nm, but taking into consideration the reliability of the proton exchange waveguide and the electrodes, this is the limit. For that reason, it is preferable that the difference in wavelength between the phase matching wavelength and the DBR wavelength is 1 nm or less.

Also, since wavelength variability due to the DBR region 7 exploits the increase in the refractive index through ion injection, it is possible to control only the wavelength to longer lengths. Consequently, the relationship between the DBR wavelength of the SHG device 3 and the phase matching wavelength at the operation temperature is preferably set so that:

DBR wavelength<phase matching wavelength

As described above, the refractive index of the DBR region 7 is changed while the current injected to the phase control region 5 of the laser diode portion is controlled, thereby achieving stable, continuous wavelength variability. With a quasi-phase matching type SHG device 3 such as that described in this embodiment, the allowable wavelength width with respect to phase matching is small at a full width at half maximum of 0.1 nm. For that reason, a continuous change in the wavelength of the laser diode as discussed in this embodiment means that the wavelength can be very accurately adjusted to the phase matching wavelength of the SHG device 3, and thus a highly efficient change in wavelength can be achieved.

In this embodiment, the two-electrode laser diode 2 having the phase control region 5 and the SHG device 3 in which the DBR region 7 is formed are directly optically coupled. Moreover, the DBR region 7 is formed in the incidence end face of the optical waveguide 6, so that the resonator length of the laser diode can be designed to be short. On the other hand, with conventional laser diodes having an external resonator made of a reflective grating, for example, the resonator length has to be long, so that the longitudinal mode interval is short, and this lowers the ability to control the longitudinal mode. As in this embodiment, providing the laser diode and the BR region close to one another allows the longitudinal mode interval to be increased to up to about 0.1 nm, and thus it is easy to achieve a single longitudinal mode through the DBR region.

Second Embodiment

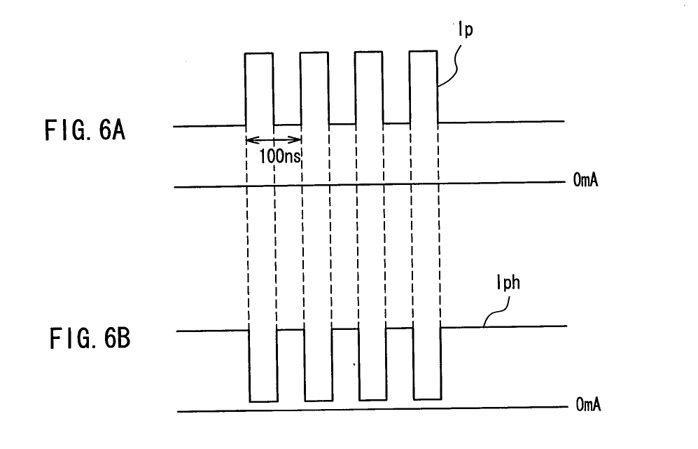

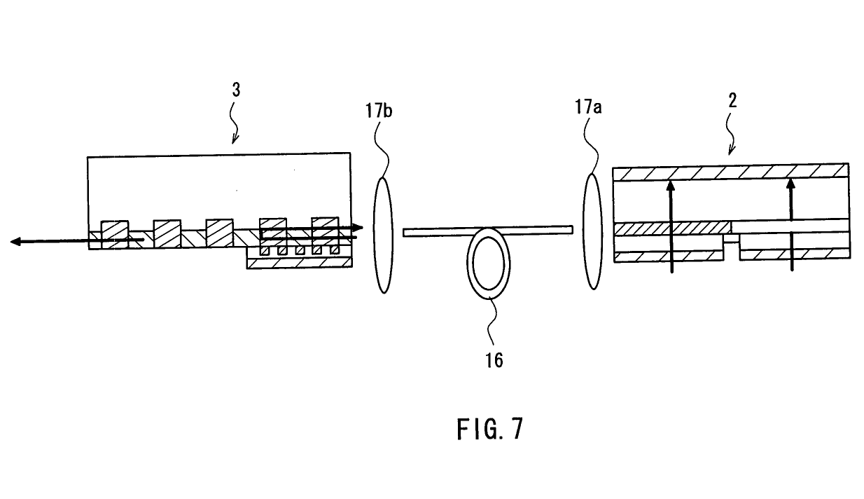

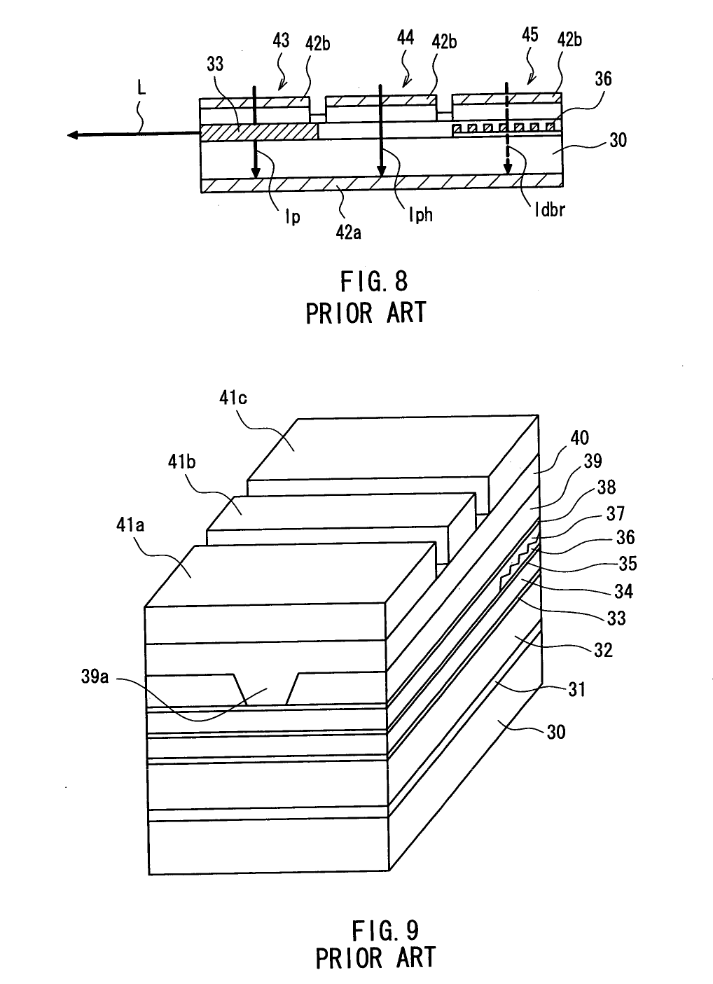

The coherent light source of the present invention has significant practical effects even in a case where the laser diode for generating the fundamental wave is directly modulated, so that the high frequency light that is obtained through wavelength conversion is emitted in a modulated state. The method of driving the coherent light source according to a second embodiment relates to such a driving method. The driving method of this embodiment is described below with reference to FIG. 6A and FIG. 6B taking as an example a case where the coherent light source configured as in FIG. 1 is adopted.

In this driving method, to modulate the laser light directly, which is the fundamental wave, a current Ip modulated as shown in FIG. 6A is injected into the active region 4 of the two-electrode laser diode 2 of FIG. 1. At the same time, a phase current Iph, whose phase is opposite that of the operation current Ip as shown in FIG. 6B, is injected into the phase control region 5. The action achieved by driving in this manner is described below.

In general, when a laser diode is driven so as to be modulated, a portion of the current that is injected into the active region is converted into heat. The heat that is generated raises the temperature of the active region, and thus the phase state within the resonator changes. More specifically, when the current that is injected is increased, the oscillation wavelength shifts toward the long wavelength side. Consequently, to keep the oscillation wavelength steady at a specific wavelength during the modulation operation, it is necessary to compensate for the shift in the phase (wavelength) within the resonator of the laser diode.

An example of a method for compensating for such a shift is described in JP 2002-43698A, in which a SHG laser is composed by combining a three-electrode DBR laser diode having an active region, a phase control region, and a DBR region with an optical waveguide-type SHG device. When driving the SHG laser, the currents or the voltages that are applied to the active region and the phase control region are complementary, that is, of reversed phases. Accordingly, the laser diode light can be modulated while the oscillation wavelength is kept stable, and as a result, high-frequency light output can be modulated stably.

A similar driving method can be adopted for the configuration of the coherent light source shown in FIG. 1 as well, since it uses a two-electrode laser diode having the active region 4 and the phase control region 5. That is, as shown in FIG. 6A and FIG. 6B, by giving the operation current Ip and the phase current Iph reversed phases, a shift in the oscillation wavelength can be suppressed. By keeping the oscillation wavelength within the allowable width of the phase matching wavelength of the SHG device even during the modulation operation, rectangular modulation waveform characteristics are obtained even for the random modulation waveforms required by optic disks, for example.

Third Embodiment

In the coherent light source of this embodiment, it is not absolutely necessary that the two-electrode laser diode having the phase control region and the SHG device in which the DBR region is formed are directly optically coupled. The coherent light source of a third embodiment, as shown in FIG. 7, is an example in which the two-electrode laser diode 2 and the SHG device 3 are not directly optically coupled.

The two-electrode laser diode 2 and the SHG device 3 are optically coupled by an optical fiber 16 and lenses 17a and 17b. The two-electrode laser diode 2 and the SHG device 3 have the same configurations as in the first embodiment. Also, they operate in substantially the same way as in the first embodiment. In this way, they can be optically coupled using lenses and an optical fiber with hardly any negative effect on the characteristics.

The above embodiments were described using examples in which an optical waveguide SHG device was used as the optical waveguide device, but the present invention can be adopted, and the same effects achieved, even if an optical waveguide that is not an SHG device is used. For example, excellent characteristics can be achieved with a coherent light source that combines a two-electrode laser diode and an optical waveguide device having a DBR region to serve as a substitute for a variable-wavelength DBR laser diode required in wavelength multiplex communications, for example. In this case as well, a large practical effect can be anticipated because the method for fabricating the laser diode is simplified.

As discussed above, with a coherent light source constituted by a two-electrode laser diode and an optical waveguide device having a DBR region, the two-electrode laser diode, like an ordinary window-structure Fabry-Perot laser diode, can be fabricated more simply than a three-electrode DBR laser diode, and thus high yield and lower costs, for example, can be anticipated. Also, as discussed above, the phase control region of the two-electrode laser diode allows stable wavelength variability and modulation characteristics to be achieved, and as a coherent light source in which optical waveguide devices have been integrated, it has a large practical effect.

The two-electrode laser diode used in the above embodiments was described as having a configuration in which the active layer of the phase control region was disordered, but it is not absolutely necessary that the active layer is disordered. For example, by providing only the phase control region with high resistance, the oscillation threshold is increased, allowing the same functions to be obtained. That is, even in this case, since the refractive index of the phase control region can be changed by injecting current, the same functions as a phase control region that has been disordered are obtained. Also, the band gap increases in conjunction with the injection of current, and gradually the loss is reduced, and thus pulsed oscillation and the modulation operation are possible. Consequently, different effects than those of a phase control region that has been disordered can be obtained.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A coherent light source, comprising:
a two-electrode laser diode provided with an active region having an active layer that emits light due to injection of a current, and a phase control region that has a layer that is contiguous with the active layer and in which a change in refractive index is caused by injection of current; and
an optical waveguide device in which a distributed Bragg reflector (hereinafter, abbreviated as DBR) region is formed;
wherein laser light that is emitted from the two-electrode laser diode is coupled optically into an optical waveguide of the optical waveguide device, and a portion of the laser light that is emitted from the two-electrode laser diode is reflected by the DBR region and returned to the two-electrode laser diode, thereby locking an oscillation wavelength.

2. The coherent light source according to claim 1,
wherein an emission end face of the two-electrode laser diode and an incidence end face of the optical waveguide device are in opposition to one another, and the laser light emitted from the two-electrode laser diode is optically coupled directly into the optical waveguide of the optical waveguide device.

3. The coherent light source according to claim 1,
wherein the laser light that is emitted from the two-electrode laser diode is coupled optically into the optical waveguide of the optical waveguide device via an optical fiber.

4. The coherent light source according to claim 1,
wherein the phase control region has an active layer that is contiguous with the active layer of the active region and that has been disordered, so that an injection of current causes a change in refractive index but does not cause laser oscillation.

5. The coherent light source according to claim 1,
wherein the optical waveguide device is a wavelength conversion device that employs second harmonic generation.

6. The coherent light source according to claim 1,
wherein an electrode is formed in the phase control region, and by applying current or voltage through the electrode, a phase state inside a resonator of the two-electrode laser diode is changed.

7. The coherent light source according to claim 2,
wherein the DBR region is disposed substantially adjacent to the emission end face of the laser diode-side.

8. The coherent light source according to claim 1,
wherein an inactive region in which the active layer has been disordered is formed in an end face portion of the two-electrode laser diode, and current is not injected into the inactive region.

9. The coherent light source according to claim 5,
wherein a wavelength difference between a phase matching wavelength of the wavelength conversion device and a DBR wavelength of the DBR region is not more than 2 nm.

10. The coherent light source according to claim 5,
wherein in an operation temperature range, a phase matching wavelength of the wavelength conversion device is longer than a DBR wavelength of the DBR region.

11. The coherent light source according to claim 1,
wherein the optical waveguide device is an optical modulator.

12. A method for driving a coherent light source according to claim 1,
wherein a current and a voltage that are supplied to the DBR region and the phase control region are changed simultaneously to allow an oscillation wavelength of the laser diode to be changed continuously.

13. A method for driving a coherent light source according to claim 1,
wherein modulation of an output intensity of the laser diode is performed by changing a current and a voltage that are supplied to the active region and the phase control region at reversed phases.
